(19) United States
(12) Patent Application Publication
(10) Pub. No.: US 2023/0080115 A1
(43) Pub. Date: Mar. 16, 2023

(54) DISPLAY APPARATUS

(71) Applicant: SeeYA Optronics Co., Ltd., Shanghai (CN)

(72) Inventor: Zhongshou HUANG, Shanghai (CN)

(21) Appl. No.: 17/687,977

(22) Filed: Mar. 7, 2022

(30) Foreign Application Priority Data
Sep. 16, 2021 (CN) 202111087132.9

(51) Int. Cl. H01L 51/52; H01L 51/56; G02B 27/01

(52) U.S. Cl. CPC H01L 51/5275; H01L 51/56; G02B 27/0172

(57) ABSTRACT

A display apparatus is provided. The display apparatus includes a container; a transparent filling substance with refractive index not less than 1.2 filled in the container; an optical lens mounted at one end of the container; a display panel disposed at another end of the container; and an aperture structure arranged between the optical lens and the display panel and configured to have a conical funnel aperture.

### CROSS-REFERENCE TO RELATED APPLICATIONS

This application is based upon and claims priority to Chinese Patent Application No. 202111087132.9, filed on Sep. 16, 2021, the entire contents of which are incorporated herein by reference.

### TECHNICAL FIELD

The present disclosure relates to a display apparatus.

### BACKGROUND

With technology development and large-scale expansion of manufacturing capacity, the organic light-emitting diode (OLED) displays have become the mainstream of portable displays and have also occupied a considerable market share of medium-sized displays and even large-sized TV displays. However, when the OLED display technology is applied to some special fields, the restrictions of the conventional structure of the OLED display on the performance of display apparatus is gradually revealed.

For example, design conflict between geometric dimensions and performance has been a challenging issue needed to be solved in Microdisplays used in augmented reality (AR) glasses and virtual reality (VR) glasses. Specifically, in applications of AR glasses and VR glasses, display apparatuses with smaller size, lighter weight and more compact package are always pursued by developers for portability. However, in order to transmit a two-dimensional optical image from the Microdisplay to eyes, with high transmission efficiency and low image aberration and distortion, a larger optical lens system is generally required, which will inevitably increase the volume and weight of the optical system. More specifically, there are two reasons for the enlargement of the optical system. First, the light-emitting surface of OLED is usually a so-called Lambertian surface with a constant brightness regardless of the angle, and the proportion of light emitted in large angles is high. Therefore, the diameter of the lens must be large enough to collect most light output from all display pixels. Second, in order to reduce image aberration and distortion, the imaging distance of the lens will be lengthened and then the volume of the entire optical system will increase accordingly. With increasing the volume of the optical system, the mechanic package for supporting and accommodating the optical system also increases and becomes heavier, thereby increasing the overall volume and weight of the display apparatuses. On the other hand, miniaturization of Microdisplays will inevitably lead to shrinking of pixel area in order to maintain total pixel count, in other words, the pixel density measured in ppi (point per inch) will increase accordingly. When the pixel area becomes smaller, the effective light emitting area and the light transmission efficiency will decrease. To recover the light loss caused by the miniaturization, therefore, a higher light collection efficiency of the optical lens is further demanded. However, the existing AR/VR apparatus is quite limited by their lens configuration and structures for better light collection efficiency.

### SUMMARY

In order to overcome the technical hurdles described above and improve light collection efficiency, the present disclosure provides a display apparatus that integrates an optical lens and a display panel without air gap between them. Specifically, an electronic display panel and an optical lens are respectively arranged at two ends of a sealed barrel-shaped container, and a filling substance with an optical refractive index not less than 1.2, such as a transparent liquid or a colloid, is filled into the space between the display panel and the optical lens. An optical image from the display panel first passes through a transparent protective layer or cover plate, and the filling substance, and then is collected by the optical lens and output outside the container. The display panel can be a flat-panel OLED, a flat-panel LCD or other types of flat-panel display. The filling substance is in contact with the optical lens and the transparent protective layer respectively. When the light from the transparent protective layer enters into the filling substance, the refraction angle will be smaller than that of the conventional display apparatus where the light transmission media is air or vacuum beyond the display panel or its cover plate. With a limited lens aperture, the brightness of the output optical image can be significantly improved if most of the light, especially including the large-angle light emitted from the display panel, are collected. The display apparatus disclosed hereinafter can improve light collection efficiency for the same lens aperture, or alternatively reduce the volume and weight of the display apparatus for the same light collection efficiency. It is therefore quite suitable for the application of wearable AR or VR display apparatus. Considering the large temperature variations in the operational environment of the wearable display apparatus, the present disclosure also provides a square-shaped or like container to hold the filling substance that can work in a wide temperature range. An aperture structure, immersed in the filling substance, shaping the output light beam of the optical lens is disclosed as well. The surface of the aperture structure maybe coated with an anti-reflection layer.

In addition to various embodiments of the display apparatus of the present disclosure, two related manufacturing methods are also provided. The first method includes steps: 1) install a display panel and auxiliary optical components such as the aperture structure; 2) inject the liquid filling substance into the container up to the height of an overflow hole; 3) mount the optical lens horizontally on the aperture structure; 4) drain off excess liquid substance through an overflow hole; 5) seal the container particularly around the optical lens and the overflow hole. The second method includes steps: 1) fix and encapsulate an optical lens, an electronic display panel and an aperture structure at two ends and inside of the container respectively; 2) inject the liquid filling substance from an injection hole until the entire container is fully filled and the excess liquid filling substance overflows from the overflow hole; 3) seal the injection hole and the overflow hole. In order to improve the reliability in a wide temperature range of the display apparatus, the present disclosure also provides a suitable operating temperature when filling the liquid filling substance.

It should be readily understood that both the foregoing general description and the following detailed description are exemplary and explanatory only, and are not intended as a limitation to the scope of the present disclosure.

### BRIEF DESCRIPTION OF THE DRAWINGS

The foregoing and other features, and advantages of the invention are apparent from the following detailed description taken in conjunction with the accompanying drawings in which:

FIG. 1 is a schematic diagram of a display apparatus according to a first embodiment of the present disclosure;

FIG. 2 is a schematic diagram of light transmitting in an aperture structure of a display apparatus in the related art;

FIG. 3 is a schematic diagram of light transmitting in an aperture structure of a display apparatus according to the first embodiment of the present disclosure;

FIG. 4 is a schematic diagram of a display apparatus according to a second embodiment of the present disclosure;

FIG. 5 is a top view of a display apparatus according to the second embodiment of the present disclosure;

FIG. 6 is a flow chart of a first method according to one embodiment of the present disclosure;

FIG. 7 is a schematic diagram of a display apparatus after step S200 of the first method is complete according to one embodiment of the present disclosure;

FIG. 8 is a schematic diagram of a display apparatus after step S310 of the first method is complete according to one embodiment of the present disclosure;

FIG. 9 is a schematic diagram of a display apparatus after step S410 of the first method is complete according to one embodiment of the present disclosure;

FIG. 10 is a schematic diagram of a display apparatus after step S510 of the first method is complete according to one embodiment of the present disclosure;

FIG. 11 is a flow chart of a second method according to one embodiment of the present disclosure;

FIG. 12 is a schematic diagram of a display apparatus after step S420 of the second method is complete according to one embodiment of the present disclosure;

FIG. 13 is a schematic diagram of a display apparatus after step S520 of the second method is complete according to one embodiment of the present disclosure;

FIG. 14 is a schematic diagram of a display apparatus according to a third embodiment of the present disclosure;

FIG. 15 is a top view of a display apparatus according to the third embodiment of the present disclosure;

FIG. 16 is a sectional view in B-B′ direction of a display apparatus under various temperatures according to the third embodiment of the present disclosure;

FIG. 17 is a sectional view in A-A′ direction of a display apparatus under varied temperatures according to the third embodiment of the present disclosure;

FIG. 18 is a schematic diagram of a display apparatus according to a fourth embodiment of the present disclosure;

FIG. 19 is a schematic diagram of a display apparatus according to a fifth embodiment of the present disclosure;

FIG. 20 is a schematic diagram of an AR/VR glass according to one embodiment of the present disclosure.

### DETAILED DESCRIPTION

In the following, embodiments of the present disclosure will be described in detail with reference to the figures. It should be understood that, the embodiments described hereinafter are only used for explaining the present disclosure, and should not be understood to limit the present disclosure. Besides, for describing the embodiments more clearly, the figures only show some aspects, instead of every aspect, of the present disclosure.

The “first”, “second” and similar words used in the present disclosure do not denote any order, quantity or importance, but are only used to distinguish different components. “comprise”, “include” and other similar words mean that the elements or objects appearing before these words, the elements or objects listed after these words, and their equivalents, but other elements or objects are not excluded. Similar words such as “connected” are not limited to physical or mechanical connections, but may include electrical connections, whether direct or indirect. “up”, “down”, etc. are only used to indicate the relative position relationship. When the absolute position of the described object changes, the relative position relationship may also change accordingly.

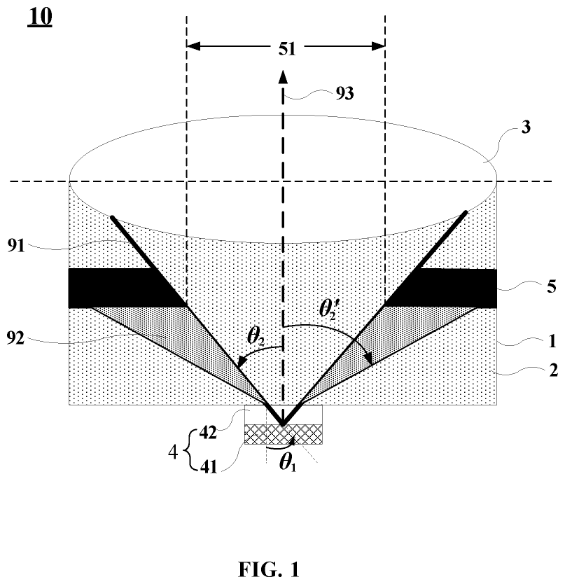

FIG. 1 is a schematic diagram of a display apparatus 10 according to a first embodiment of the present disclosure. The display apparatus includes an optical lens 3, an aperture structure 5 and a display panel 4, which are arranged from top to bottom in sequence. A filling substance 2 is filled into the spaces between the three components. In some embodiments, the filing substance 2 is transparent and a refractive index of the filling substance 2 is not less than 1.2. The filling substance 2 may be in a liquid form, or in a solid colloid form obtained by solidifying a liquid substance. In the illustrated embodiment, the optical lens 3 is a double convex lens having two convex surfaces. In some embodiment, one side of the optical lens 3 is in contact with the filling substance 2. In other embodiments, the optical lens 3 may be convex lens with different shapes, such as a plano-convex lens which has one convex surface and one flat surface, or a convex-concave lens, or a compound lens. The optic lens 3 provides converging functionality for output light from the display panel 4.

In the first embodiment, the display panel 4 includes a light-emitting surface 41 and a transparent protective layer 42. The transparent protective layer 42 of the display panel 4 is in contact with the filling substance 2. The light-emitting surface 41 maybe the light-emitting surface of an OLED display panel, or other type micro-display panel suitable for wearable apparatus. The transparent protective layer 42 can be a transparent glass or a transparent film, with one side laminated on the light-emitting surface 41 and another side in contact with the filling substance 2. The optical lens 3 is arranged in a manner that its principal imaging plane is in parallel to the light-emitting surface 41, and its optical axis 93 passes through the center of the light-emitting surface 41. Hereinafter, the principal imaging plane of the optical lens 3 is defined as a virtual plane which is perpendicular to the lens optical axis that a lumped effect of refractions no matter how many times between incident light and the optical lens 3 can be referred as one refraction at the principal imaging plane or the principal imaging plane is a plane perpendicular to the lens optical axis at which all incident light coming from the focal point refracts.

The working principle of the display apparatus of the first embodiment will be described below with reference to FIG. 1.

As illustrated in FIG. 1, the display apparatus 10 includes an aperture structure 5, the aperture structure 5 is arranged between the optical lens 3 and the display panel 4 to define the maximum angle of output light, and it is in contact with the filling substance. A center of the aperture structure 5 is on the optical axis 93 of the optical lens 3. Without collimating optics or prism films, the spatial distribution of the light emitted from the display panel 4 approximately follows Lambertian's law, that is, the light intensity at all space angle is approximately identical.

The light emitted from the display panel 4 will be refracted at the interface between the transparent protective layer 42 and the filling substance 2, following Snell's law that the product of the sine of the refracted angle θ₂ and the refractive index of the filling substance 2 is equal to the product of the sine of the incident angle θ₁ and the refractive index of the transparent protective layer 42. Without the filling substance, as those display apparatus in prior arts, the space between the optical lens 3 and the transparent protective layer 42 is filled with air or inert gas. Since the refractive index of air is approximately equal to 1, and the refractive index of a glass cover is approximately 1.4, the refraction angle will increase to θ₂, resulting in a significant portion of large angle light being blocked by the aperture structure 5. In the prior arts, an optical lens with a larger diameter would have been adopted to collect those large angle light, which increases the size and weight of the optical system at the rate of the cube of the diameter of the optical lens. Increased dimensions and weight of the optical system will become obstacle for the application of wearable AR or VR glasses. An alternative technique to collect those large angle light, might be reducing the distance between the optical lens and the display panel, or equivalently reducing the F-number of the optical lens, which is defined as a ratio between the focal length to the diameter of the optical lens. However, larger F-number may result in significant image aberrations such as chromatic aberrations and image distortion, and is generally not preferred in a imaging system.

In the present disclosure, as shown in FIG. 1, a filling substance 2 with a refractive index larger than or equal to 1.2 is filled the space between the optical lens 3 and the display panel 4, the angle of the light entering the filling substance 2 will be reduced. In a simplified scenario, as illustrated in the embodiment of FIG. 1, the refractive index of the filling substance 2 is made approximately equal to the refractive index of the transparent protective layer 42, and therefore the space angle of output light beam is kept the same in the filling substance 2 as in the transparent protective layer 42, as illustrated in the cone-shaped light beam 91. As a result, some light (indicated by shaded area 92) that would have been blocked in the prior arts, will pass through the aperture structure 5 and finally collected by the optical lens 3. In other words, comparing to the prior arts, this embodiment of the present disclosure can output an image with higher brightness, more uniform resolution, less optical aberration and perhaps in a more compact and lighter package.

The ability of the optical lens 3 to collect light from the display panel 4 can be characterized by the numerical aperture NA of the optical lens 3, and NA=n·Sin(θ), wherein θ is half of the space angle of the output light beam 91, n is refractive index of the medium between the optical lens 3 and the display panel 4. Therefore, the higher the refractive index of the medium, the more light emitted by the OLED display panel can be collected by the optical lens 3.

Additional advantage of this embodiment lies in the ability to output more image details of an ultra-high-resolution display panel. An optical image placed at the focal point of the optical convex lens, will be transformed into a collimated light beam. The intensity and phase distribution of the collimated light on the beam cross-section is a two-dimensional Fourier-transform spectral. Light intensity of the near-axial ray represents image information in lower spatial frequency, while the light intensity of the far-axial ray represents image information in higher spatial frequency. In other words, the more large-angle light from the display panel 4 is collected by the optical lens 3, the richer image details can be output.

The ultimate image resolution is determined by the diffractive Airy disk, that is, the minimum spatial distance xₘᵢₙ that can be distinguished under the diffraction limit is determined by the following formula:

xₘᵢₙ≈(0.61·λ)/NA, wherein λ is the wavelength of the light, and NA is the numerical aperture of the optical lens. Obviously, the larger the numerical aperture, the smaller the minimum spatial distance and thus the higher the ultimate resolution. It should be pointed out that the above diffraction limit needs to be considered not only when the size of the pixel is comparable to the wavelength of light. Even if the size of the pixel is 3 microns, the minimum width of one of the three RGB sub-pixels may be less than 1 micron. Even if the minimum width of a sub-pixel is greater than 1 micron, its edges may contain components of higher spatial frequencies, which can be seen in Fourier transform of a rectangular sub-pixel image. High spatial frequency components improve the sharpness in visually observed images, giving better image recognition and vivid visual experience.

To sum up, the display apparatus of the first embodiment in FIG. 1 provides three major advantages: a more compact and lighter optical imaging system; improvement of the brightness of the output image; improvement of the image sharpness. With the reduction of the minimum spatial distance that the optical imaging system can distinguish, the display panel can be made smaller, and the optical components, such as optical lens etc., can be made smaller. Therefore, the integration of components in a limited space can be higher, which is of great advantage for the display apparatus of AR glasses or VR glasses.

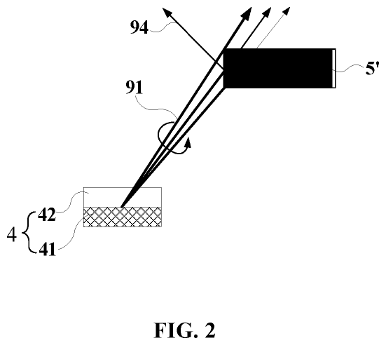

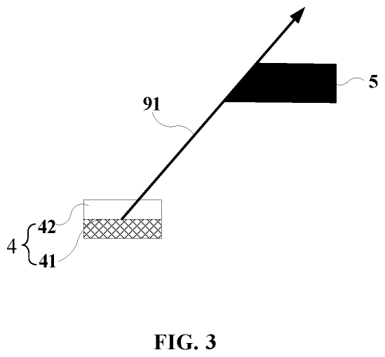

FIG. 2 is a schematic diagram of light transmitting in an aperture structure of a display apparatus in the related art. As shown in FIG. 2, the aperture structure 5′ has a vertical inside sidewall. FIG. 3 is a schematic diagram of light transmitting in an aperture structure of a display apparatus according to the first embodiment of the present disclosure. As shown in FIG. 3, the aperture structure 5 has an inclined inner sidewall. The light intensity inside the material of the aperture structure is attenuated exponentially with the depth along a path of light transmission. In the display apparatus of related art shown in FIG. 2, the edge of the cone-shaped light beam exhibits a gradually transition zone caused by the vertical sidewall, which may slightly reduce image sharpness because of losing high spatial frequency component. Another drawback of the vertical sidewall is optical interference caused by light reflection (indicated by reference number 94) on the vertical sidewall. The display apparatus of the present disclosure addresses these issues by configuring the aperture structure 5 with an inclined sidewall as shown in FIG. 3. As illustrated in FIG. 3, an angle of the inclined wall of the aperture structure 5 with the optical axis 93 is approximately equal to the angle 9, of the cone-shaped light beam 91 as illustrated in FIG. 1. In the embodiment of the present disclosure, the through hole of the aperture structure 5 is configured to be a conical funnel structure with a large opening close to the optical lens 3, and a small opening close to the display panel 4. A virtual conical apex of the conical funnel structure is located on a side of the light-emitting surface 41 away from the transparent protective layer 42. Both the center of the display panel and the virtual conical apex are on the optical axis of the optical lens 3.

Further, the aperture structure 5 may be made of metal materials, or non-metal materials. The non-metal materials include resins doped with carbon powder or rubbers, such as black conductive rubber, black conductive resin, etc. In some embodiments, the aperture structure 5 is made of copper or aluminum. A light-absorbing layer to reduce light reflection may be provided on the surface of the aperture structure 5 where light may interact with. The light-absorbing layer can be obtained by painting the inclined wall with black materials such as black polyvinyl chloride (PVC) or black resin, or oxidizing the metal surface.

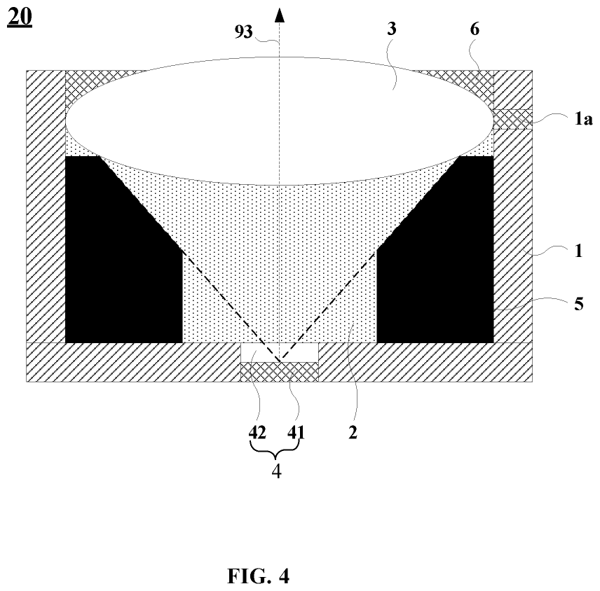

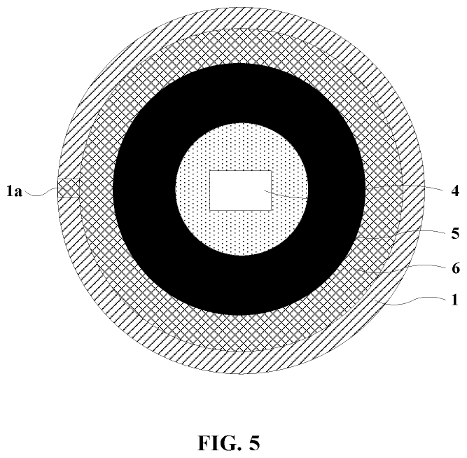

FIG. 4 and FIG. 5 schematically illustrate a display apparatus 20 according to a second embodiment of the present disclosure, and FIG. 4 is a cross-sectional view, FIG. 5 is a top view. The display apparatus 20 includes a barrel-shaped container 1 and a display panel 4 mounted at the center of the bottom surface of the container, an optical lens 3 mounted on the top of the container, an aperture structure 5 with an inclined sidewall and positioned between the display panel 4 and the optical lens 3, a liquid filling substance 2 filled into the space inside the barrel-shaped container.

In some embodiments, the barrel-shaped container 1 may be a cylindrical container, made of polyvinyl chloride (PVC) or metal. Referring to FIG. 4 and FIG. 5, the barrel-shaped container 1 includes a round bottom plate and an annular side wall surrounding the bottom plate. The side wall and the bottom plate are perpendicular to each other and seamlessly assembled. The bottom plate may be configured to be slightly thicker than the side wall to accommodate thermal expansions while minimize warpage of the bottom plate. That is, a thickness of a side wall may be configured to be smaller than a thickness of a bottom plate.

The display panel 4, is located in the bottom plate.

In the second embodiment, the display panel 4 is embedded in an opening of the bottom plate of the container 1, and its signal lines and control lines of the display panel are pulled out from the bottom of the display panel 4. In other embodiments, the display panel 4 is directly mounted on the bottom plate of the container 1 and immersed in the filling substance, and its signal lines and control lines are pulled out through a hole on the container.

In the second embodiment, the through hole of the aperture structure 5 includes a conical section and a cylindrical section connected to the conical section. At the assembled position, the cylindrical section is located adjacent to a bottom of the container 1 and the conical section is adjacent to the optical lens. The cross section (or diameter) of the through hole gradually changes in the conical section, and decreases to the minimum value at the connection with the cylindrical section. The inner sidewall of the conical section is a part of a conical surface, and a virtual apex of the cone located at the center of the light-emitting surface.

As shown in FIG. 4, the aperture structure 5 is mounted on the bottom plate of the container 1, its outer diameter or outer dimension fits the inner side wall of the container 1, and its top circular wall holds the optical lens 3. That is, the aperture structure 5 in this embodiment of the present disclosure is also a support for the optical lens 3, thus it can be easy to keep the distance from the optical lens 3 to the display panel 4 approximately equal to the focal length of the optical lens 3 during the assembly process.

Because the black coating on the aperture structure may not absorb all light reflection inside the container 1, all the inner surface of the container 1, which houses the display panel 4, the liquid filling substance 2, the aperture structure 5 and the optical lens, may be coated with a light-absorbing layer, which can be obtained by painting the inner surface of the container 1 with black polyvinyl chloride (PVC) or black resin, or blackening the inner surface of the metal container through surface oxidation.

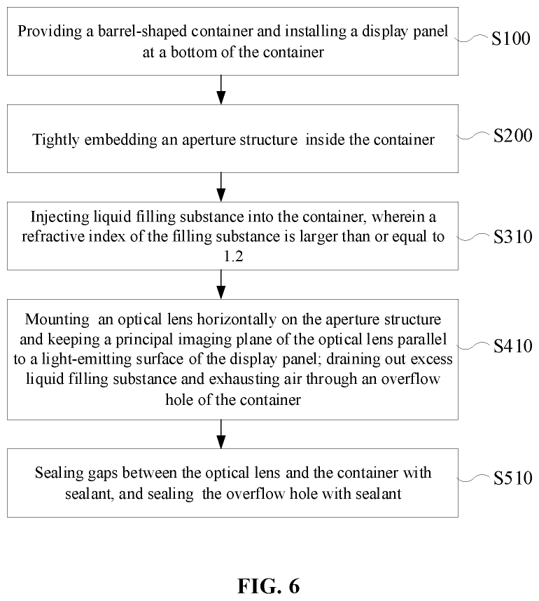

In the second embodiment, an overflow hole 1a may be disposed on the side wall of the container 1, through which the excess liquid is drained out of the container during the process of assembling the optical lens 3. In this way, the optical lens 3 is evenly placed on the top circular wall of the aperture structure 5, and excess liquid and air bubbles are squeezed out of the container. The overflow hole 1a is then sealed by the sealant 6 and the upper edge of the optical lens 3 and the side wall of the container 1 are encapsulated and cured. To ensure no leakage of liquid and air, as the last step of the assembly process, the gap between the bottom of the container 1 and the surroundings of the display panel 4 is also sealed and cured with sealant. The assembly process joined with FIG. 6 to FIG. 13, will be further described in detail later.

As described in previous embodiment, the substance filled in the container 1 may be a liquid substance with a refractive index larger than that of the air (refractive index of the air is approximately 1 in room temperature). Considering the refractive index of an optical glass is approximately around 1.4, a filling substance having refractive index not less than 1.2 may be selected. In some embodiments, deionized water and glycerin may be selected as the filling substance in the display apparatus because the refractive index of the deionized water is approximately 1.33, and the refractive index of glycerin is approximately 1.47.

Assuming the refractive index of the transparent protective layer 42 is n1, the refractive index of the liquid filling substance is n2, and the refractive index of the optical lens 3 is n3, the transparent protective layer, the filling substance, and the optical lens may be selected based on the refractive index to achieve the goal of increasing light collection efficiency. In some embodiments, the condition n2≥n1 is satisfied when the liquid filling substance and the transparent protective layer are selected. In some embodiments, the condition n3≥n2≥n1 is satisfied when the optical lens, the liquid filling substance and the transparent protective layer are selected. In some embodiments, the condition n2=(n1+n3)/2 is satisfied when the optical lens, the liquid filling substance and the transparent protective layer are selected. That is, the refractive index of the liquid filing substance is an average value of a refractive index of the protective layer and a refractive index of the optical lens

Because the liquid filling substance 2 may interact with the metal material of the metal container 1, deionized water is used as the liquid filling substance to prevent electrochemical corrosion. The liquid filling substance may be a mixed solution of antifreeze and deionized water, wherein the antifreeze may be anti-corrosion liquid as well, and the volume ratio of the antifreeze is between 20% and 50%. The more antifreeze, the lower the freezing point. A mixed solution with more than 20% antifreeze by volume can ensure normal operation of the display apparatus at minus 20 degrees Celsius. The antifreeze may include at least one of the following substances: methanol, ethanol, ethylene glycol, and glycerol. The molecular formula of the methanol is CH3OH, the molecular formula of ethanol is C2H5OH, and the molecular formula of ethylene glycol is C2H4(OH)2, the molecular formula of glycerol is C3H5(OH)3, and the last two substances are generally called glycerol.

In other embodiment, silicone oil can be used for the liquid filling substance 2 The silicone oil is insoluble in water and has a freezing point of minus 50 degrees Celsius, and a boiling point of 101 degrees Celsius, so it will not freeze or volatilize in a normal application environment. Silicone oil is usually colorless and transparent with a refractive index of 1.4, which may be selected as the filling substance in the present disclosure.

The present disclosure also provides a method for manufacturing the above-mentioned display apparatus. The two manufacturing methods of display apparatus are described with reference from FIG. 6 to FIG. 13. FIG. 6 illustrates a flow chart of a first method, and the method includes the following assembly steps:

S100: providing a container and installing a display panel at a bottom of the container. The container may be barrel-shaped.

S200: tightly embedding an aperture structure inside the container. Tightly embedding the aperture structure inside the container means that both the bottom and the outer side wall of the aperture structure 5 are seamlessly in contact with the inner surface of the barrel-shaped container 1. That is, the aperture structure is placed in the container in a manner that there is no space existed between an outer side wall of the aperture structure and an inner side wall of the container. In some embodiments, the aperture structure includes an aperture with a conical section as described above.

S310: injecting liquid filling substance in the container, wherein a refractive index of the filling substance is larger than or equal to 1.2. In some embodiment, the filing substance is de-bubbled;

S410: mounting an optical lens evenly or horizontally on the aperture structure and keeping a principal imaging plane of the optical lens parallel to the light-emitting surface of the display panel, and draining out excess liquid substance and exhausting air through an overflow hole located on a wall of the container;

S510: sealing gaps between the optical lens and the container with sealant, and sealing the overflow hole with sealant.

From assembly step S310 to S510, the temperatures of the container, the optical lens, the aperture structure, the display panel and the liquid filling substance are kept between about 36 degrees Celsius and about 60 degrees Celsius, a preferable assembly temperature range. This temperature control during assembly will effectively prevent void or air bubbles being generated inside the container in operation, as long as the operational temperature of the display apparatus is kept lower or slightly higher than the preferable assembly temperature range. This is because that the metal shell of the container shrinks as the temperature goes down while the liquid filling substance is kept incompressible, which causes the metal container to have a deformation towards a round-shape in order to contain the same volume liquid filling substance inside the container. Of course, implementing this temperature control should also make sure no detrimental impact to the quality of the output image, such as image distortion or out focus.

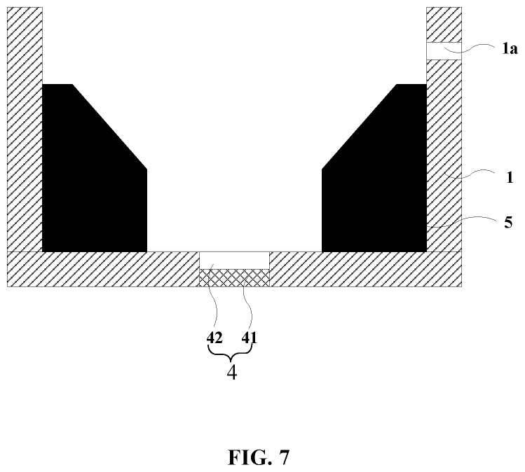

The assembly steps from S100 to S510 are further described in detail below with reference to FIG. 7 to FIG. 10. Exemplarily, this embodiment is illustrated with a liquid filling substance. In other alternative embodiments, the filling substance may be colloid material, such as liquid colloid and the like.

In the first step S100, a display panel 4 is installed in an embedding hole at the bottom of a barrel-shaped container 1. In some embodiments, display panel 4 may be embedded and installed in such a manner that the outer surface of the transparent protective layer 42 is slightly higher than the bottom plate of the container. The gap between the display panel 4 and the embedding hole is then sealed with a sealant to prevent leakage of liquid and air.

Any void or air bubbles in the filling substance may refract or scatter light that is emitted from the display panel. Therefore, materials with similar thermal expansion coefficient should be selected to make the container 1 and the aperture structure 5, to prevent generation of void or air bubbles inside the container as temperature changing. In addition, materials having similar surface electrochemical properties should be selected for the container and aperture structure, to minimize risks of electrochemical corrosions.

In other embodiments, no embedding hole is made on the bottom plate of the container 1, and the display panel 4 is directly mounted on a surface of the bottom plate. In this case, however, a through hole is provided on the container 1 to pull out signal lines and control lines of the display panel.

In this embodiment, at least one overflow hole 1a is provided on the side wall or shell of the container 1, to drain out excess liquid or exhaust air during assembly process.

Corresponding to step S200, as shown in FIG. 7, an aperture structure 5 is provided, and the aperture structure 5 is embedded into the barrel-shaped container 1 so that that both the bottom and the outer side wall of the aperture structure 5 are seamlessly in contact with the inner surface of the barrel-shaped container 1.

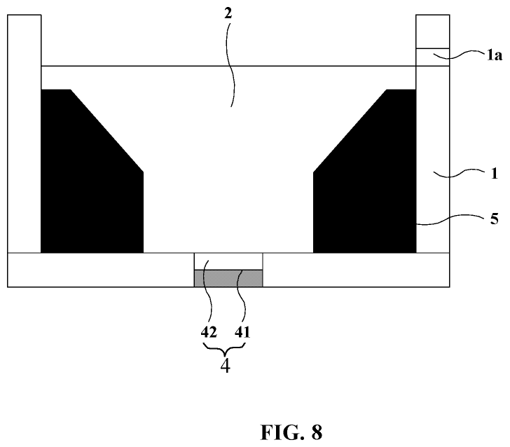

Then, corresponding to the step S310, as shown in FIG. 8, the liquid filling substance 2 is injected into the container 1 through the upper opening until the liquid filling substance reaches the overflow hole 1a. To prevent air bubble generation, which may be originated from gas molecular resolved in the liquid filling substance or residual air attached on surface inside the container, the liquid filling substance may need to be de-bubbled before or during the injection.

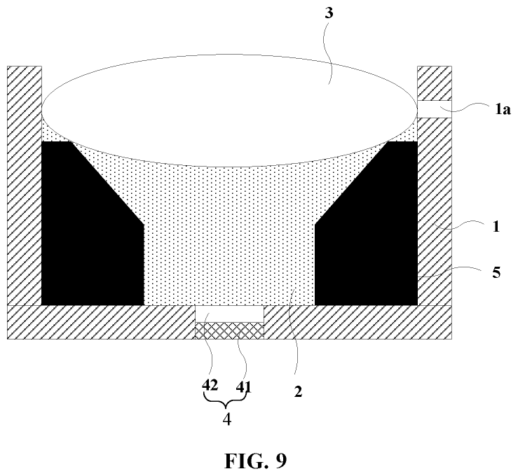

After that, corresponding to the step S410, as shown in FIG. 9, the optical lens 3 is evenly or horizontally mounted on the aperture structure 5. In some embodiments, the optical lens 3 is mounted by a mechanical grabber such as a vacuum suction cup (not shown in the figure). In the assembly process of the optical lens, a principal imaging plane of the optical lens 3 should be kept in parallel to the light-emitting surface 41 of the display panel 4, or the optical lens 3 is evenly mounted on the aperture structure 5.

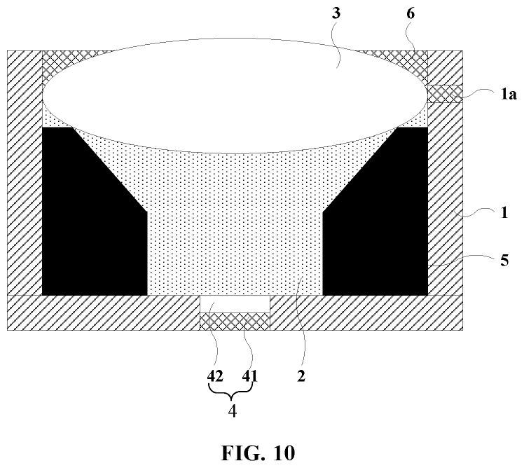

Finally, corresponding to the last step S510, as shown in FIG. 10, a sealant 6 is applied to the periphery of the optical lens 3 to seal the gap between the optical lens 3 and the container 1. The sealant is also applied to the overflow hole 1a. As the sealant 6 is cured, the optical lens 3 and the barrel-shaped container 1 are glued and sealed together, which completes the manufacture process of the display apparatus.

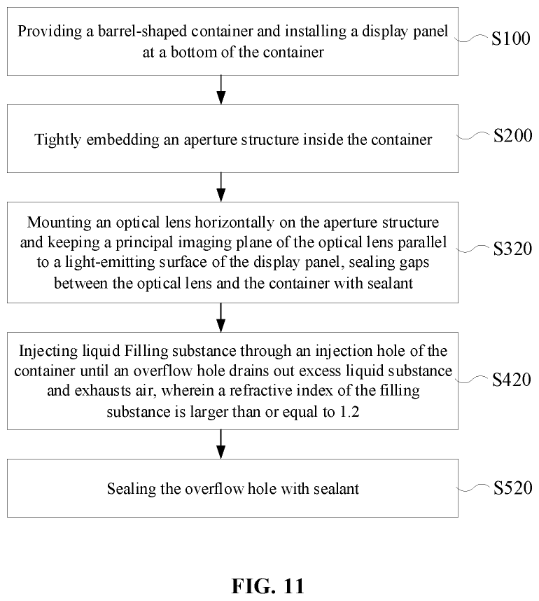

FIG. 11 illustrated a flow chart of a second method according to the present disclosure, which includes the following steps:

S100: providing a barrel-shaped container and installing a display panel at a bottom of the container;

S200: tightly embedding an aperture structure with a conical funnel structure inside the container;

S320: mounting an optical lens horizontally on the aperture structure and keeping a principal imaging plane of the optical lens parallel to a light-emitting surface of the display panel, sealing gaps between the optical lens and the container with sealant;

S420: injecting liquid substance through an injection hole of the container until an overflow hole drains out excess liquid substance and exhausts air, the liquid filling substance in the container and a refractive index of the filling substance is larger than or equal to 1.2;

S520: sealing the overflow hole with a sealant.

In S320 to S520, the temperatures of the container, the optical lens, the aperture structure, the display panel and the liquid filling substance are kept between about 36 degrees Celsius and about 60 degrees Celsius. When the display apparatus is used, as long as its temperature is kept lower or slightly higher than above assembly temperature range, the risk of bubble generation is negligible.

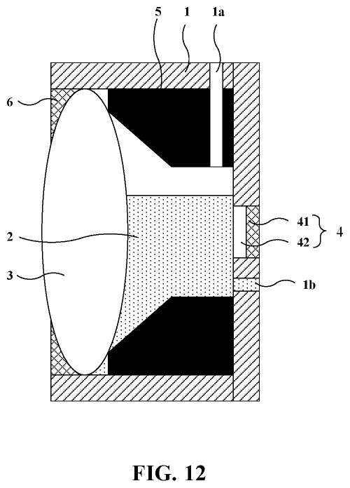

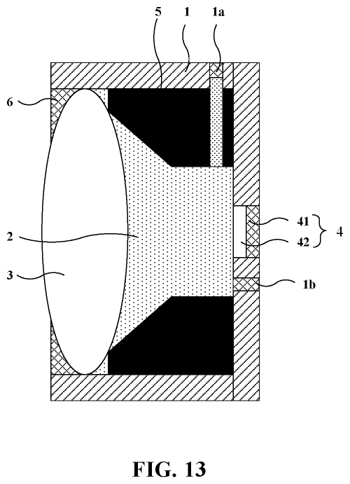

The processes of the second manufacturing method are described in detail below with reference to FIG. 12 and FIG. 13. Exemplarily, this embodiment is illustrated with a liquid filling substance. In other alternative embodiments, the filling substance may be other filling material, such as liquid colloid and the like.

Specifically, steps S100 and S200 in the second and the first manufacturing method are essentially identical. In the step S320, only the gap between the optical lens 3 and the barrel-shaped container 1 is sealed, while the overflow hole 1a is left open, to allow the excess liquid filling substance and any volatile solvent of the sealant to be removed from the overflow hole 1a.

The major difference between the first and the second manufacturing methods is the sequence of injection of the liquid filling substance, that injection step in the second manufacturing method is conducted after encapsulating the optical lens 3 and curing the sealant. Correspondingly, in addition to the overflow hole 1a, an injection hole 1b is provided on the bottom of the barrel-shaped container 1 (see FIGS. 12-13).

In S420, as shown in FIG. 12 wherein the sealant 6 is cured, the barrel-shaped container rotates 90° so that the opening of the overflow hole 1a faces upward. Then the liquid filling substance 2 is injected through the injection hole 1b until the overflow hole 1a drains out the excess filling substance 2 and exhausts all the air. The liquid filling substance 2 also needs to be de-bubbled to remove the gas before being injected to the container 1. During the injection, the exit of the overflow hole 1a should always be kept higher than the entrance of the injection hole 1b.

In S520, as shown in FIG. 13, the overflow hole 1a and the injection hole 1b are respectively sealed with a cured sealant 6, as completion of manufacturing the display apparatus.

The assembling and encapsulating steps in the first and second manufacturing methods described above can be carried out in an atmosphere, or in a closed chamber in a relatively low pressure or even vacuum. Carrying out these process steps in a low pressure or vacuum space can further minimize air trapped inside the container 1 and in the liquid filling substance, thereby preventing air bubbles generation later on as the body temperature changes or body movement.

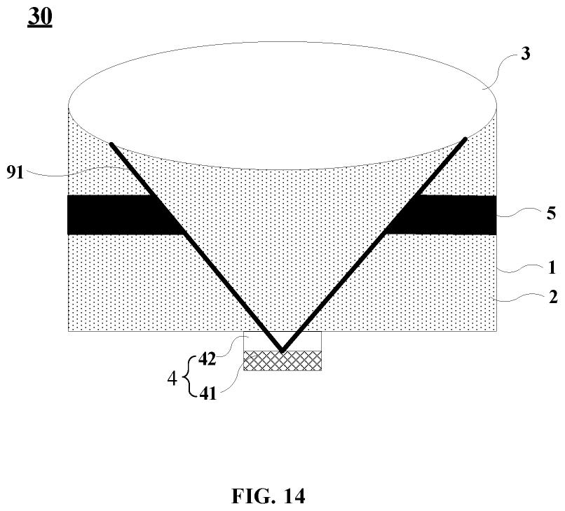

FIG. 14 to FIG. 17 schematically illustrate a display apparatus 30 according to a third embodiment of the present disclosure. Similar to the first embodiment, the display apparatus 30 includes a barrel-shaped container 1 and a display panel 4 arranged at the bottom center of the container, and an optical lens 3, a liquid filling substance 2 and an aperture structure 5 with an inclined surface.

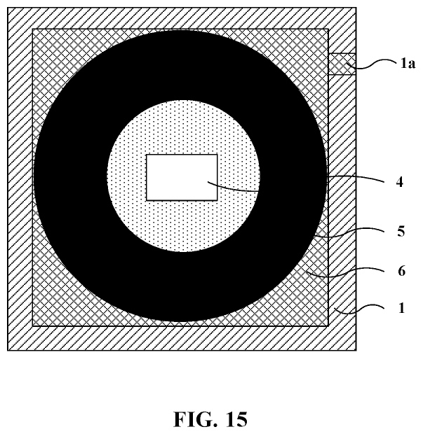

As shown in FIG. 15, the container 1 of the third embodiment is not a barrel with a drum shaped sidewall as given in the first embodiment, but rather a rectangular container formed by a rectangular bottom plate and four sidewalls. The four sidewalls are standing vertically and confining the rectangular bottom plate. The rectangular container may provide a flexibility to deal with container body expansion or shrinkage as temperature changes, while maintaining its capacity unchanged to accommodate the uncompressible liquid filling substance.

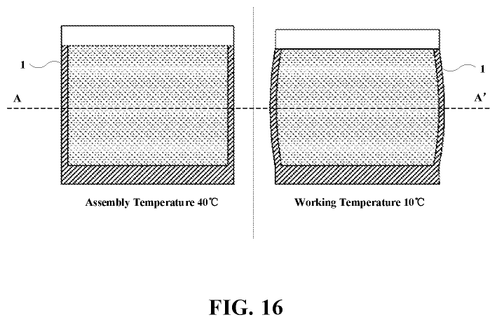

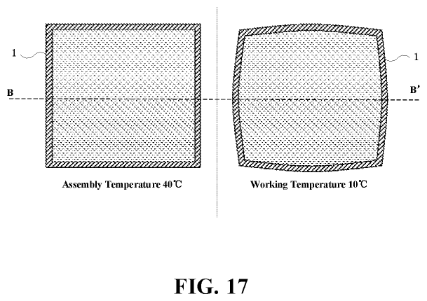

FIG. 16 and FIG. 17 are respectively two sets of cross-sectional views of a display apparatus referring temperature as variable. The cross-section A-A′ is in parallel to the display surface and the cross-sectional view of the cross-section A-A′ is shown in FIG. 17. The cross-section B-B′ is in perpendicular to the display surface and the cross-sectional view of the cross-section B-B′ is shown in FIG. 16. When the working temperature of the display apparatus is 40 degrees Celsius, which is approximately equal to its assembly temperature, the container 1 maintains the original rectangular shape; when the working temperature of the display apparatus drops to 10 degrees Celsius, which is much lower than the assembly temperature, the surface area of the metal shell of the container 1 tends to shrink but the container may deform into a drum-like exterior shape to maintain the original capacity for the liquid filling substance. As such, risks of cracking on the container shell and leakage of the liquid filling substance are minimized.

As temperature rising, the surface area of the metal shell of the container 1 will expand. Compressed by the atmospheric pressure, the metal shell of the container 1 may deform into a concave-shape to maintain the capacity of the internal space. In this way, the generation of air bubbles or void inside the container is minimized to some extent.

In some embodiments, the rectangular bottom plate is made thicker than the metal shell of the container sidewall. In this way, when the temperature changes, the deformation of the barrel-shaped container 1 mainly occurs on the side wall, and the bottom of the barrel-shaped container 1 will not be deformed, thereby ensuring the display panel abutting against the bottom of the container 14 will not be affected.

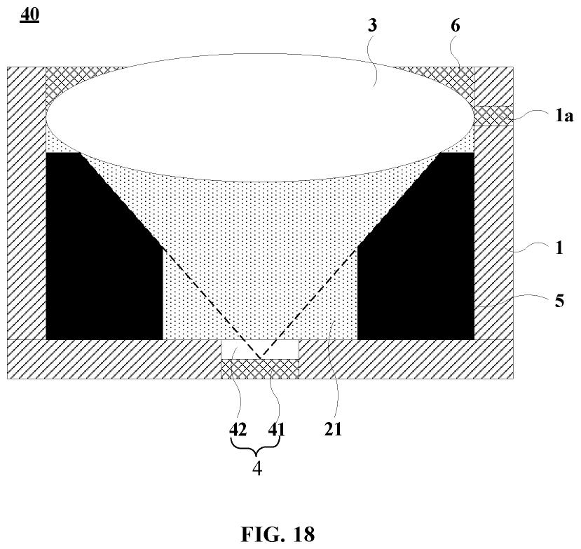

FIG. 18 schematically illustrates a display apparatus 40 according to a fourth embodiment of the present disclosure, wherein the filling substance is a transparent colloid 21 with less fluidity than a pure liquid. The transparent colloid 21 can be resin colloids, such as epoxy resin or silicone. The liquid colloid 21 may cover all the inner surface and fill out all the corners inside of the container due to hydrophilicity of the inner surface of the container and internal pressure of the gel form filling substance cause by assembling the optical lens 3. This process will further squeeze out residual air from the container.

In the fourth embodiment, the advantage of using the transparent colloid 21 is that the density of colloid or resin may be higher than that of ordinary liquids, and correspondingly, its optical refractive index maybe larger than a liquid substance, which is beneficial for the optical lens to collect more light from the display panel.

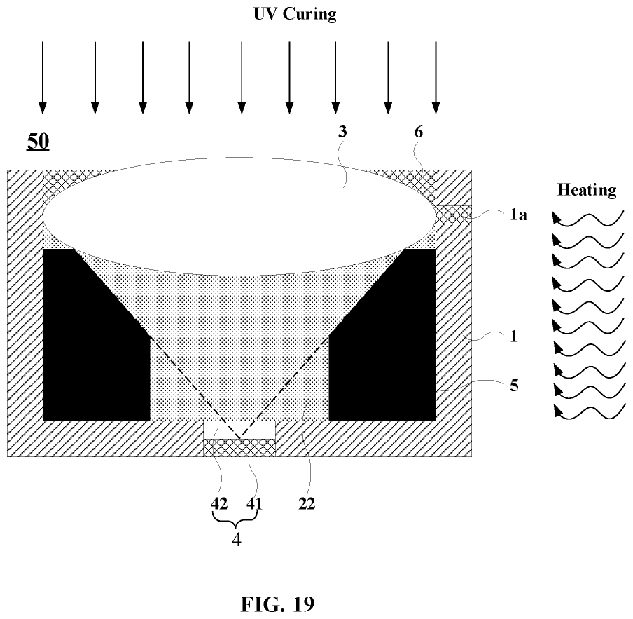

FIG. 19 schematically illustrates a display apparatus according 50 to a fifth embodiment of the present disclosure, wherein the filling substance is a curable transparent colloid 22. After completion of the injection of the curable colloid 22, ultraviolet (UV) light or infrared radiation (heat) is applied to the container, through the optical lens or through heat transmissible container body. The volatile gas generated during the curing process of the colloid 22 is released from the container 1 through the at least one overflow hole 1a or the provided pinholes.

In addition to the above-mentioned advantages, the container fully filled with the colloid or hardened resin behaviors as a solid optical fixture, having superior stability and durability. No matter how to place, rotate or shake the assembled display apparatus, the relative positions and distances between the various components inside the container are completely fixed, providing a stable optical image.

UV or thermal curable materials can be selected from the following: acrylic polymer, epoxy polymer, polycarbonate, allyl diglycolate (CR-39), and other resins. The refractive index of these materials reaches about 1.7, which greatly improves the optical performance of the optical lens system.

Similar to the case in the first embodiment, the refractive index of the transparent colloids n2 should be larger than or equal to 1.2, and the equation n1 n2 n3 is satisfied. In another embodiment, the refractive indexes of the filling substance (e.g., the refractive index of the transparent colloids n2, the refractive index of the optic lens n3 and the refractive index of the transparent protective layer n1) satisfy the equation: n2=(n1+n3)/2.

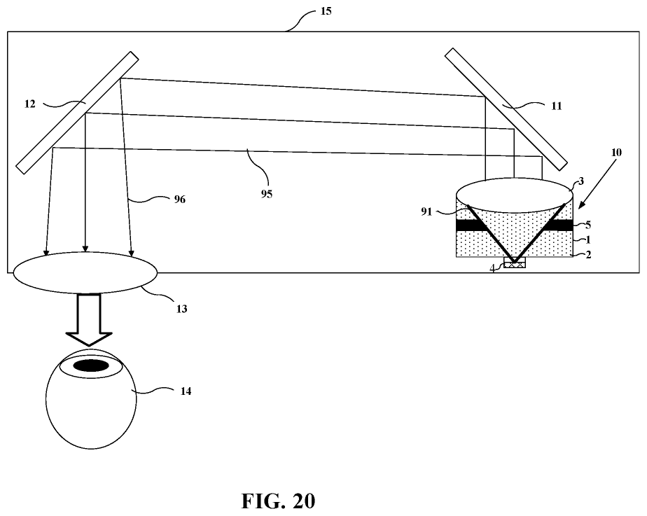

FIG. 20 is a schematic diagram of an AR/VR glass according to one embodiment of the present disclosure, where the AR glass includes a display apparatus 10, a light guide fixture 15, a first reflector 11, a second reflector 12 and an optical lens 13. These components, along with the focusing lens 3, form an optical imaging system, transmitting the optical image from the display panel to human eyes 14.

In this embodiment, the display panel 4 may be a silicon-based OLED display, with built-in OLED pixel array, row scanning lines, data lines and external power supply lines. The silicon-based OLED display has the advantages of high image resolution, high integration of various functions, low power consumption, compact, light weight, and etc.

A Si-based full color OLED display panel 4 can be realized by combining a color filter array and a white light OLED film, which significantly simplifies manufacture process with a single evaporation of OLED film without using a complex and expensive fine metal mask (FMM). In other embodiments, the display panel 4 can be display panel based on different technology or is configured in different manners.

The above descriptions of the present disclosure are given in connection with some specific and preferred embodiments, other embodiments within the scope of the concept of the present disclosure are not limited to the above descriptions. Modifications and substitutions can be made without departing from the spirit and scope of the present disclosure.

What is claimed is:

1. A display apparatus comprising:
a barrel-shaped container;
a transparent filling substance filled in the container, wherein a refractive index of the filling substance is larger than or equal to 1.2;
an optical lens mounted at one end of the container, and one side of the optical lens is in contact with the filling substance; and
a display panel mounted at other end of the container, wherein the display panel comprises a light-emitting surface and a protective layer, wherein the protective layer is transparent and configured to be in contact with the filling substance;
wherein a principal imaging plane of the optical lens is in parallel to the light-emitting surface, and an optical axis of the optical lens passes through a center of the light-emitting surface.

2. The display apparatus according to claim 1, wherein the refractive index of the filling substance is larger than or equal to a refractive index of the protective layer.

3. The display apparatus according to claim 1, wherein the refractive index of the filling substance is smaller than or equal to a refractive index of the optical lens.

4. The display apparatus according to claim 2, wherein the refractive index of the filling substance is smaller than or equal to a refractive index of the optical lens.

5. The display apparatus according to claim 1, wherein the refractive index of the filling substance is equal to an average value of a refractive index of the protective layer and a refractive index of the optical lens.

6. The display apparatus according to claim 1, further comprising: an aperture structure arranged between the optical lens and the display panel, wherein the aperture structure is configured to define the maximum angle of a light beam, and the aperture structure is in contact with the filling substance, a center of a through hole of the aperture structure coincides with the optical axis of the optical lens.

7. The display apparatus according to claim 6, wherein the through hole of the aperture structure includes a conical funnel structure with a large opening close to the optical lens, and a small opening close to the display panel.

8. The display apparatus according to claim 7, wherein the aperture structure includes metal materials, and a light-absorbing layer is provided on a surface of the aperture structure and the surface faces the light beam.

9. The display apparatus according to claim 1, wherein the display panel is mounted on a bottom of the container, and signal lines and control lines of the display panel are pulled out through a hole on the container.

10. The display apparatus according to claim 1, wherein the display panel is embedded on a bottom of the container, and signal lines and control lines are pulled out from a bottom of the display panel.

11. The display apparatus according to claim 1, wherein the container has a side wall and a bottom plate, wherein the bottom plate is in contact with the display panel, wherein a cross-section parallel to the optical axis of the container is rectangular, and a thickness of the side wall is smaller than a thickness of the bottom plate.

12. The display apparatus according to claim 1, wherein the filling substance is in a liquid form or in a solid colloid form obtained by solidifying a liquid substance.

13. The display apparatus according to claim 12, wherein at least one overflow hole is provided on a side wall of the container for draining out excess liquid substance or exhausting air during assembly.

14. The display apparatus according to claim 12 wherein at least one injection hole is provided to the container for injecting the liquid substance.

15. The display apparatus according to claim 12, wherein the filling substance is a mixture solution of deionized water and antifreeze, or silicone oil, wherein colloid is resin colloid or silica gel.

16. The display apparatus according to claim 15, wherein the antifreeze comprises one of methanol, ethanol, ethylene glycol and glycerol.

17. A method of manufacturing a display apparatus, comprising:
a. providing a barrel-shaped container and installing a display panel at a bottom of the container;
b. tightly embedding an aperture structure inside the container such that both a bottom and an outer side wall of the aperture structure are seamlessly in contact with an inner surface of the barrel-shaped container, wherein the aperture structure has a conical funnel aperture;
c. injecting liquid substance into the container, wherein a refractive index of the filling substance is larger than or equal to 1.2;
d. mounting an optical lens horizontally on the aperture structure and keeping a principal imaging plane of the optical lens parallel to a light-emitting surface of the display panel; draining out excess liquid filling substance and exhausting air through an overflow hole of the container; and
e. sealing gaps between the optical lens and the container with a sealant, and sealing the overflow hole with a sealant; wherein temperatures of the container, the optical lens, the aperture structure, the display panel and the liquid filling substance are kept between about 36 degrees Celsius and about 60 degrees Celsius in steps c to e.

18. A method of manufacturing a display apparatus, comprising:
a. providing a barrel-shaped container and installing a display panel at a bottom of the container;
b. tightly embedding an aperture structure inside the container such that both a bottom and an outer side wall of the aperture structure are seamlessly in contact with an inner surface of the barrel-shaped container, wherein the aperture structure has a conical funnel aperture, wherein the aperture structure has a conical funnel structure;
c. mounting an optical lens horizontally on the aperture structure and keeping a principal imaging plane of the optical lens parallel to a light-emitting surface of the display panel, and sealing gaps between the optical lens and the container with sealant;
d. injecting liquid substance through an injection hole of the container until an overflow hole drains out excess liquid substance and exhausts air, wherein a refractive index of the filling substance is larger than or equal to 1.2;
e. sealing the overflow hole with sealant;
wherein temperatures of the container, the optical lens, the aperture structure, the display panel and the liquid filling substance are kept between about 36 degrees Celsius and about 60 degrees Celsius in steps c to e.
